(19) United States
(12) Patent Application Publication
(10) Pub. No.: US 2025/0157980 A1
(43) Pub. Date: May 15, 2025

(54) SEMICONDUCTOR PACKAGE

(71) Applicant: SAMSUNG ELECTRONICS CO., LTD., Suwon-si (KR)

(72) Inventor: Jinkyeong SEOL, Suwon-si (KR)

(73) Assignee: SAMSUNG ELECTRONICS CO., LTD., Suwon-si (KR)

(21) Appl. No.: 18/741,540

(22) Filed: Jun. 12, 2024

(30) Foreign Application Priority Data
Nov. 13, 2023 (KR) 10-2023-0156542

(51) Int. Cl. H01L 23/00; H01L 23/48; H01L 23/498; H01L 25/065; H10B 80/00

(52) U.S. Cl. CPC H01L 24/80; H01L 23/481; H01L 24/06; H01L 24/08; H01L 25/0657; H01L 23/49816; H01L 24/05; H01L 2224/05647; H01L 2224/06051; H01L 2224/08146; H01L 2224/80379; H01L 2224/80895; H01L 2224/80896; H10B 80/00

(57) ABSTRACT

A semiconductor package includes semiconductor chips each including at least one of a front insulating layer or a rear insulating layer, the semiconductor chips bonded to each other through direct bonding between the front insulating layer and the rear insulating layer. At least one of the semiconductor chips includes a device layer including an interconnection structure, and a conductive pattern on a front surface of the device layer. The conductive pattern includes pad patterns electrically connected to the interconnection structure, and a dummy pattern spaced apart from the pad patterns. The dummy pattern includes first dummy patterns between the pad patterns to overlap the pad patterns in a first direction, and a second dummy patterns between the first dummy patterns to overlap the pad patterns in the second direction. The second dummy patterns are spaced apart from the first dummy patterns.

### CROSS-REFERENCE TO RELATED APPLICATION

This application claims priority to Korean Patent Application No. 10-2023-0156542 filed on Nov. 13, 2023 in the Korean Intellectual Property Office, the disclosure of which is incorporated by reference herein in its entirety.

### BACKGROUND

### 1. Field

The present disclosure relates to semiconductor package.

### 2. Description of Related Art

In accordance with the trend of miniaturization and the implementation of high performance of semiconductor packages, the development of a system-in-package (SiP) technology for embedding a plurality of semiconductor chips performing different functions in a single package has been required. In order to form a fine interconnection connecting semiconductor chips to each other within a package, a technology for forming through-silicon vias (TSVs) and bonding semiconductor chips to each other through bonding pads has been used.

### SUMMARY

One or more embodiments provide a semiconductor package that may have improved electrical properties and/or reliability of a front surface of a semiconductor chip.

According to an aspect of an example embodiment, a semiconductor package includes: a plurality of semiconductor chips, each of the plurality of semiconductor chips including at least one of a front insulating layer and a rear insulating layer, adjacent semiconductor chips of the plurality of semiconductor chips being bonded to each other through direct bonding between the front insulating layer of a first one of the adjacent semiconductor chips and the rear insulating layer of a second one of the adjacent semiconductor chips. At least one of the plurality of semiconductor chips includes a device layer including an interconnection structure, and a conductive pattern on a front surface of the device layer. The conductive pattern includes a plurality of pad patterns electrically connected to the interconnection structure, and a dummy pattern spaced apart from the plurality of pad patterns. The dummy pattern includes a plurality of first dummy patterns between the plurality of pad patterns and overlapping the plurality of pad patterns in a first direction and not in a second direction, and a plurality of second dummy patterns between the plurality of first dummy patterns and overlapping the plurality of pad patterns in the second direction and not in the first direction, wherein the plurality of second dummy patterns are spaced apart from the plurality of first dummy patterns.

According to an aspect of an example embodiment, a semiconductor package includes: a plurality of semiconductor chips, each of the plurality of semiconductor chips including at least one of a front insulating layer and a rear insulating layer, adjacent semiconductor chips of the plurality of semiconductor chips being bonded to each other through direct bonding between the front insulating layer of a first one of the adjacent semiconductor chips and the rear insulating layer of a second one of the adjacent semiconductor chips. At least one of the plurality of semiconductor chips includes: a plurality of front pads; the front insulating layer around each of the plurality of front pads; a device layer on a rear surface of the front insulating layer, the device layer including an interconnection structure electrically connected to the plurality of front pads; a support insulating layer between the device layer and the front insulating layer; and a conductive pattern between the interconnection structure and the plurality of front pads and around the conductive pattern. The conductive pattern includes: a plurality of pad patterns electrically connected between the interconnection structure and the plurality of front pads; and a dummy pattern spaced apart from the plurality of front pads and the plurality of pad patterns. The dummy pattern includes a plurality of first dummy patterns extending in a second direction between the plurality of pad patterns, and the plurality of first dummy patterns overlap the plurality of pad patterns in a first direction. The plurality of first dummy patterns are spaced apart from each other in the first direction between two adjacent pad patterns, among the plurality of pad patterns.

According to an aspect of an example embodiment, a semiconductor package includes: a semiconductor chip including: a front insulating layer; a plurality of front pads surrounded by the front insulating layer; a device layer on a rear surface of the front insulating layer and including an interconnection structure electrically connected to the plurality of front pads; a conductive pattern between the interconnection structure and the plurality of front pads; a support insulating layer between the device layer and the front insulating layer and around the conductive pattern; a semiconductor substrate on a rear surface of the device layer; a through-electrode passing through the semiconductor substrate; and a rear insulating layer on a rear surface of the semiconductor substrate. The conductive pattern includes a plurality of pad patterns electrically connected between the interconnection structure and the plurality of front pads; and a dummy pattern spaced apart from the plurality of front pads and the plurality of pad patterns. The dummy pattern includes a plurality of dummy patterns arranged around each of the plurality of pad patterns, and each of the plurality of dummy patterns extending in an extension direction that is not bent.

### BRIEF DESCRIPTION OF DRAWINGS

The above and other aspects, features, and advantages of the disclosure will be more clearly understood from the following detailed description, taken in conjunction with the accompanying drawings, in which:

FIG. 1 is a cross-sectional view of a semiconductor package according to one or more example embodiments of the disclosure;

FIG. 2A is an enlarged view of portion A of the semiconductor package of FIG. 1;

FIG. 2B is an enlarged view of portion B of the semiconductor package of FIG. 1;

FIG. 3A is a plan view of a semiconductor package and a conductive pattern according to one or more example embodiments of the disclosure;

FIG. 3B is a plan view of a semiconductor package and a conductive pattern according to one or more example embodiments of the disclosure;

FIG. 3C is a plan view of a semiconductor package and a conductive pattern according to one or more example embodiments of the disclosure;

FIG. 3D is a plan view of a semiconductor package and a conductive pattern according to one or more example embodiments of the disclosure;

FIG. 3E is a plan view of a semiconductor package and a conductive pattern according to one or more example embodiments of the disclosure;

FIG. 3F is a plan view of a semiconductor package and a conductive pattern according to one or more example embodiments of the disclosure;

FIG. 4A is a plan view of a semiconductor package and a conductive pattern according to one or more example embodiments of the disclosure;

FIG. 4B is a plan view of a semiconductor package and a conductive pattern according to one or more example embodiments of the disclosure;

FIG. 4C is a plan view of a semiconductor package and a conductive pattern according to one or more example embodiments of the disclosure;

FIG. 4D is a plan view of a semiconductor package and a conductive pattern according to one or more example embodiments of the disclosure;

FIG. 4E is a plan view of a semiconductor package and a conductive pattern according to one or more example embodiments of the disclosure;

FIG. 5A is an enlarged view of a semiconductor package according to one or more example embodiments of the disclosure;

FIG. 5B is an enlarged view of a semiconductor package according to one or more example embodiments of the disclosure;

FIG. 6A is a cross-sectional view of a method of manufacturing a semiconductor package according to one or more example embodiments of the disclosure;

FIG. 6B is a cross-sectional view of a method of manufacturing a semiconductor package according to one or more example embodiments of the disclosure;

FIG. 6C is a cross-sectional view of a method of manufacturing a semiconductor package according to one or more example embodiments of the disclosure;

FIG. 6D is a cross-sectional view of a method of manufacturing a semiconductor package according to one or more example embodiments of the disclosure;

FIG. 6E is a cross-sectional view of a method of manufacturing a semiconductor package according to one or more example embodiments of the disclosure;

FIG. 6F is a cross-sectional view of a method of manufacturing a semiconductor package according to one or more example embodiments of the disclosure;

FIG. 6G is a cross-sectional view of a method of manufacturing a semiconductor package according to one or more example embodiments of the disclosure;

FIG. 7A is a cross-sectional view of a method of manufacturing a semiconductor package according to one or more example embodiments of the disclosure;

FIG. 7B is a cross-sectional view of a method of manufacturing a semiconductor package according to one or more example embodiments of the disclosure;

FIG. 7C is a cross-sectional view of a method of manufacturing a semiconductor package according to one or more example embodiments of the disclosure; and

FIG. 7D is a cross-sectional view of a method of manufacturing a semiconductor package according to one or more example embodiments of the disclosure.

### DETAILED DESCRIPTION

The detailed description of the disclosure to be described later refers to the accompanying drawings which, by way of example, illustrate specific embodiments in which the disclosure may be practiced. These example embodiments are described in sufficient detail to enable those skilled in the art to practice the disclosure. It should be understood that the various embodiments of the disclosure are different from each other but are not necessarily mutually exclusive. For example, one or more example embodiments of specific shapes, structures, and characteristics described herein may be implemented in another embodiment without departing from the spirit and scope of the disclosure. In addition, it should be understood that the location or arrangement of individual components within each disclosed embodiment may be changed without departing from the spirit and scope of the disclosure. Accordingly, the detailed description set forth below is not intended to be taken in a limiting sense, and the scope of the disclosure is limited only by the appended claims, with all equivalents as claimed by those claims. Like reference numbers in the drawings indicate the same or similar function throughout the various aspects.

Expressions, “at least one of A and B” and “at least one of A or B” and “at least one of A or B” should be interpreted to mean any one of “A” or “B” or “A and B.” As another example, “performing at least one of steps 1 and 2” or “performing at least one of steps 1 or 2” means the following three juxtaposition situations: (1) performing step 1; (2) performing step 2; (3) performing steps 1 and 2.

Hereinafter, example embodiments of the disclosure will be described in detail with reference to the accompanying drawings such that those skilled in the art may easily practice the disclosure.

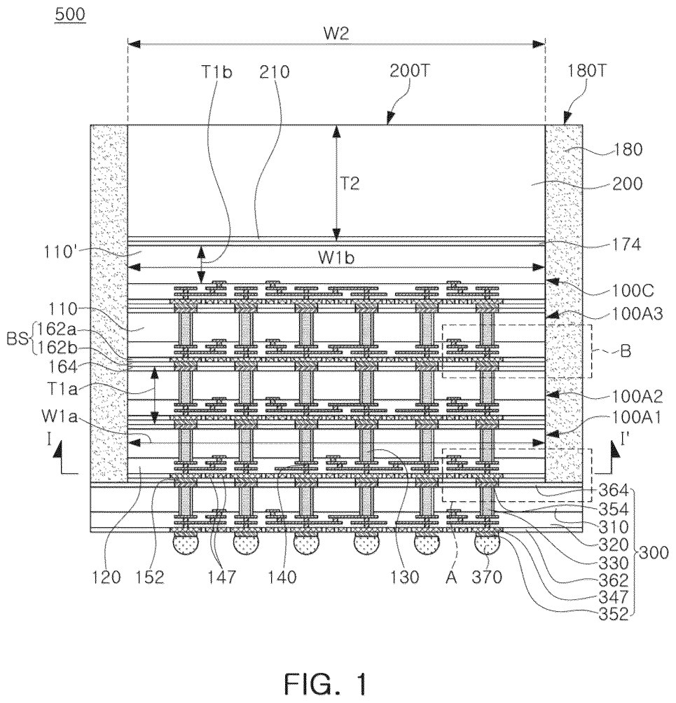

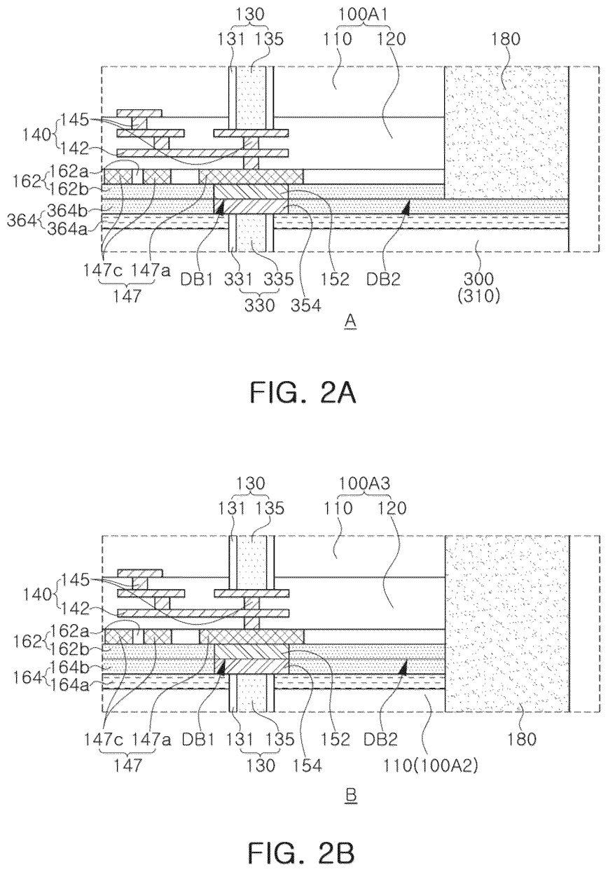

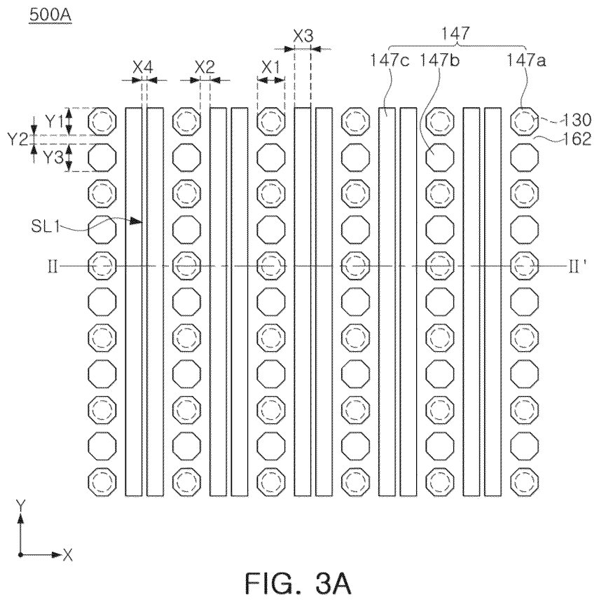

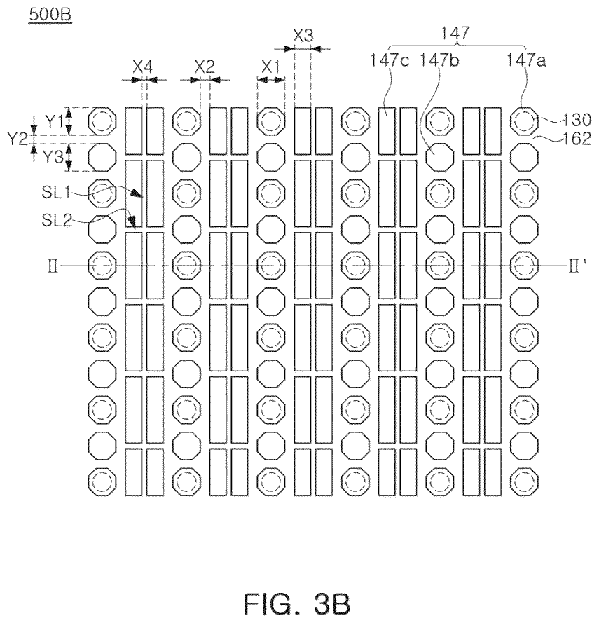

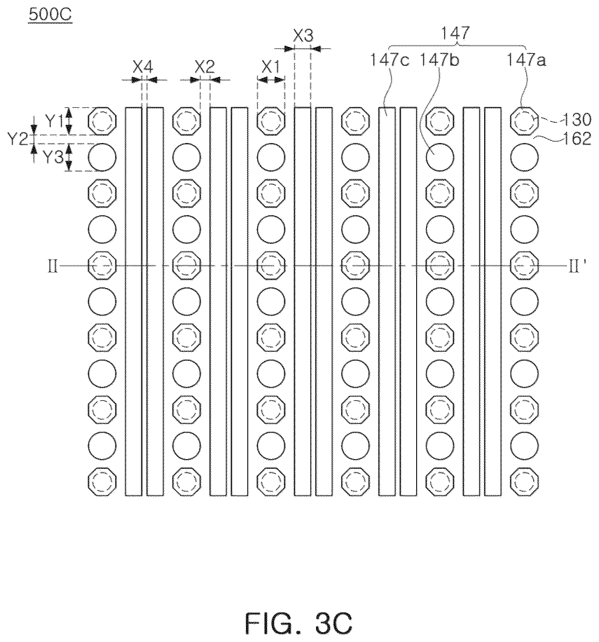

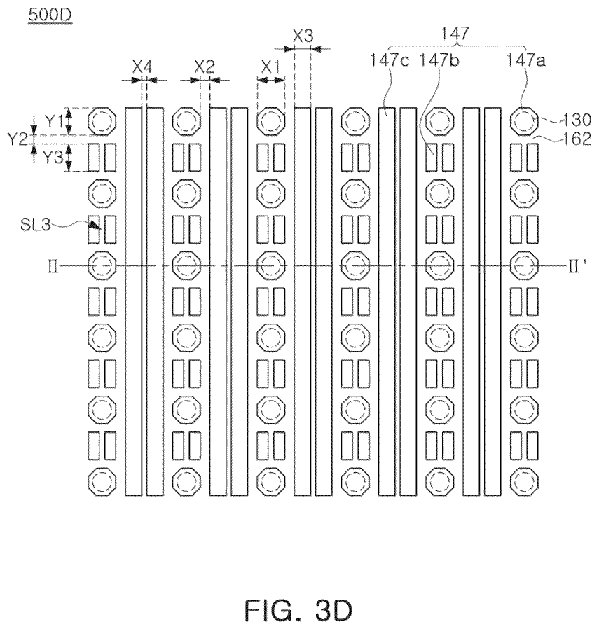

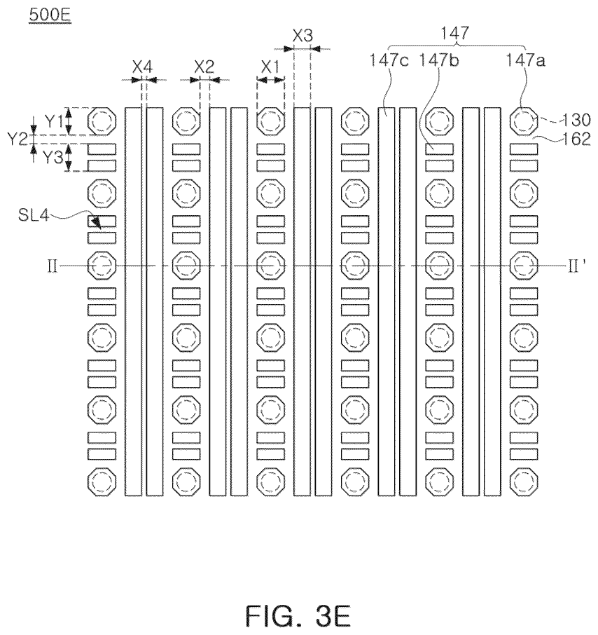

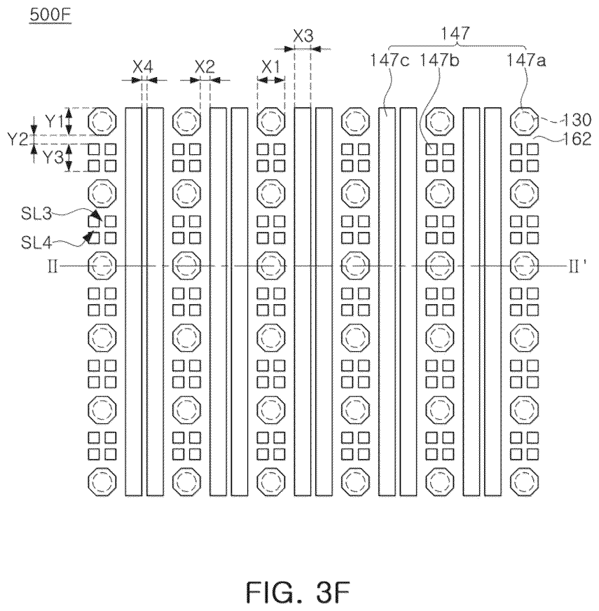

FIG. 1 illustrates an X-Z cross-section of a semiconductor package taken along line II-II′ of FIG. 3A. FIG. 3A illustrates an X-Y cross-section of a semiconductor package taken along line I-I′ of FIG. 1. FIG. 2A is an enlarged view of portion A of FIG. 1. FIG. 2B is an enlarged view of portion B of FIG. 1.

Referring to FIGS. 1, 2A, 2B, and 3A, semiconductor packages 500 and 500A according to one or more example embodiments of the disclosure may include at least one of a plurality of semiconductor chips 100A1, 100A2, 100A3, and 100C, and may further include a base structure 300 disposed on a lower side of each of the plurality of semiconductor chips 100A1, 100A2, 100A3, and 100C. Each of the plurality of semiconductor chips 100A1, 100A2, 100A3, and 100C may include a front insulating layer 162b, a plurality of front pads 152, a device layer 120, semiconductor substrates 110 and 110′, a conductive pattern 147, and a support insulating layer 162a. Each of the plurality of semiconductor chips 100A1, 100A2, and 100A3 may include a through-electrode 130, a rear insulating layer 164, and a plurality of rear pads 154. FIG. 1 illustrates a structure in which the number of semiconductor chips 100A1, 100A2, 100A3, and 100C is four, but the number of semiconductor chips 100A1, 100A2, 100A3, and 100C is not particularly limited.

The plurality of semiconductor chips 100A1, 100A2, 100A3, and 100C each may be a memory chip. For example, the memory chip may be a volatile memory chip such as a dynamic random access memory (DRAM) or a static random access memory (SRAM), or a nonvolatile memory chip such as a phase-change random access memory (PRAM), a magnetoresistive random access memory (MRAM), a ferroelectric random access memory (FeRAM), or a resistive random access memory (RRAM). Alternatively, some semiconductor chips, among the plurality of semiconductor chips 100A1, 100A2, 100A3, and 100C, each may be a memory chip and other semiconductor chips each may be a logic chip. The logic chip may be, for example, a microprocessor, analog element, or digital signal processor, and may control operations of memory chips. For example, a combination of the plurality of semiconductor chips 100A1, 100A2, 100A3, and 100C may be a high bandwidth memory (HBM) DRAM.

The base structure 300 may include lower connection pads 352, disposed on a lower surface thereof, and upper connection pads 354, disposed on an upper surface thereof. For example, the base structure 300 may have a width (that is, an area), wider than widths W1a and W1b (that is, an area) of the plurality of semiconductor chips 100A1, 100A2, 100A3, and 100C. The base structure 300 may include a substrate body 310 and an interconnection circuit, connecting the lower connection pads 352 and upper connection pads 354 to each other within the substrate body 310. A connection bump 370 may be attached to the lower connection pads 352 of the base structure 300. The connection bump 370 may be, for example, a solder ball or a conductive bump. The connection bump 370 may be electrically connected to the semiconductor package 500 and a printed circuit board such as a motherboard. Alternatively, the connection bump 370 may be electrically connected to an interposer for redistribution on the lower side. The base structure 300 may be implemented as a semiconductor chip, but embodiments of the disclosure are not limited thereto. For example, depending on the design, the base structure 300 may be implemented as the interposer.

The semiconductor substrates 110 and 110′ may include a semiconductor such as silicon. For example, the semiconductor substrate 110 may include various impurity regions for an individual element, and an element isolation structure such as a shallow trench isolation (STI) structure. The semiconductor is not limited to silicon, and may include at least one of germanium, silicon carbide (SiC), gallium arsenide (GaAs), indium arsenide (InAs), and indium phosphide (InP). For example, the element includes a planar metal oxide semiconductor FET (MOSFET), a FinFET in which an active region has a fin structure, a multi bridge channel FET (MBCFET™) or gate-all-around transistor including a plurality of channels vertically stacked on the active region, or a vertical FET (VFET), but embodiments of the disclosure are not limited thereto.

Each of the through-electrodes 130 may have a pillar structure, passing through the semiconductor substrate 110. The through-electrodes 130 may not pass through the semiconductor substrate 110′. An upper end of the through-electrode 130 may be connected to the plurality of rear pads 154, and a lower end of the through-electrode 130 may be electrically connected to the plurality of front pads 152 through an interconnection structure 140. The through-electrode 130 may include a via plug 135 and an insulating liner 131, surrounding (disposed around) the via plug 135. The insulating liner 131 may electrically isolate the via plug 135 from the semiconductor substrate 110. Through-electrodes 330, an insulating liner 331, and a via plug 335 of the base structure 300 may be implemented in substantially the same manner as the through-electrodes 130, the insulating liner 131, and the via plug 135.

The device layer 120 may include an interconnection structure 140, connected to a plurality of individual elements formed on front surfaces (lower surfaces) of the semiconductor substrates 110 and 110′. The interconnection structure 140 may include an interconnection layer 142 and an interconnection via 145. For example, the interconnection structure 140 may have a structure in which a plurality of interconnection layers 142 are stacked in a Z-direction, and may include a plurality of interconnection vias 145, electrically connecting the plurality of interconnection layers 142 to each other in the Z-direction. The interconnection structure 140 may be electrically connected to a plurality of front pads 152 disposed on a lower side of the device layer 120. The interconnection layer 142 and the interconnection via 145 may include at least one of copper (Cu), a copper alloy, aluminum (Al), and an aluminum alloy. The metal material is not limited thereto, and may be implemented as at least one of nickel (Ni), gold (Au), cobalt (Co), tantalum (Ta), tellurium (Te), titanium (Ti), tungsten (W), and alloys thereof (for example, TiN and TaN). A space of the device layer 120 in which the interconnection structure 140 is not disposed may be filled with an insulating layer. For example, the insulating layer may include at least one of silicon oxide (SiO), silicon nitride (SiN), silicon oxynitride (SiON), silicon oxycarbide (SiOC), and silicon carbonitride (SiCN). A device layer 320 of the base structure 300 may be implemented in substantially the same manner as the device layer 120.

The plurality of front pads 152 may be arranged on a front surface (lower surface) of each of the plurality of semiconductor chips 100A1, 100A2, 100A3, and 100C, and may provide electrical paths for exteriors of the plurality of semiconductor chips 100A1, 100A2, 100A3, and 100C. The exteriors of the semiconductor chips 100A2, 100A3, and 100C may be the plurality of rear pads 154 of the semiconductor chips 100A1, 100A2, and 100A3 immediately therebelow. That is, the plurality of front pads 152 may be connected to the plurality of rear pads 154, thereby providing an electrical connection path between the plurality of semiconductor chips 100A1, 100A2, 100A3, and 100C. The plurality of rear pads 154 may be arranged on a rear surface (upper surface) of each of the plurality of semiconductor chips 100A1, 100A2, and 100A3, and may be connected between the plurality of front pads 152 and the through-electrodes 130.

A front surface (lower surface) and a rear surface (upper surface) of each of the plurality of front pads 152 and the plurality of rear pads 154 may have a polygonal or circular shape, and may have a width, wider than a line width of an interconnection of the interconnection layer 142. Each of the plurality of front pads 152 and the plurality of rear pads 154 may include a metal material capable of mutual coupling while having high conductivity, such as copper (Cu) or a copper alloy. The metal material is not limited to copper, and may also be implemented as at least one of aluminum (Al), nickel (Ni), gold (Au), cobalt (Co), tantalum (Ta), tellurium (Te), titanium (Ti), tungsten (W), and alloys thereof. For example, the plurality of front pads 152 and the plurality of rear pads 154 may be temporarily bonded to each other so as to be in direct contact with each other, and may then be firmly coupled to each other through mutual diffusion of copper using a high-temperature annealing process.

The front insulating layer 162b may surround (be disposed around) the plurality of front pads 152, and the rear insulating layer 164 may surround (be disposed around) the plurality of rear pads 154. Front surfaces (lower surfaces) and rear surfaces (upper surfaces) of the front insulating layer 162b and the plurality of front pads 152 may be respectively coplanar with each other, and front surfaces (lower surfaces) and rear surfaces (upper surfaces) of the rear insulating layer 164 and the plurality of rear pads 154 may be respectively coplanar with each other.

Each of the front insulating layer 162b and the rear insulating layer 164 may include SiO₂. When the front insulating layer 162b and the rear insulating layer 164 are bonded to each other, oxygen of SiO₂ may form a covalent bond to silicon. Accordingly, the front insulating layer 162b and the rear insulating layer 164 may have strong bonding strength. An insulating material, included in the front insulating layer 162b and the rear insulating layer 164, is not limited to silicon oxide, and may be implemented as at least one of SiN, SiCN, and tetraethyloxysilane (TEOS).

For example, the rear insulating layer 164 may include a first insulating film 164a and a second insulating film 164b. The first insulating film 164a may prevent undesired electrical connection between the plurality of rear pads 154 and the semiconductor substrate 110. In addition, the plurality of rear pads 154 may be buried in the second insulating film 164b such that rear surfaces (upper surfaces) thereof are exposed. The exposed rear surfaces (upper surfaces) of the plurality of rear pads 154 may have a rear surface (upper surface), substantially planar with a rear surface (upper surface) of the second insulating film 164b. In some example embodiments, the first and second insulating films 164a and 164b may be formed of the same material, but embodiments of the disclosure are not limited thereto, and may be formed of different materials. For example, the first insulating film 164a may include silicon nitride or silicon oxynitride, and the second insulating film 164b may include silicon oxide.

Adjacent semiconductor chips of the plurality of semiconductor chips 100A1, 100A2, 100A3, and 100C may be bonded to each other through direct bonding DB2 between the front insulating layer 162b and the rear insulating layer 164. In addition, adjacent semiconductor chips of the plurality of semiconductor chips 100A1, 100A2, 100A3, and 100C may be electrically connected to each other through direct bonding DB1 between the plurality of front pads 152 and the plurality of rear pads 154. The direct bonding DB1 may be intermetallic bonding, and the direct bonding DB2 may be inter-dielectric bonding. A combination of the direct bonding DB1 and the direct bonding DB2 may be hybrid bonding.

A lowermost semiconductor chip 100A1, among the plurality of semiconductor chips 100A1, 100A2, and 100A3, may be directly bonded to the base structure 300 in a similar manner to the direct bonding DB1 and the direct bonding DB2 described above. Specifically, the plurality of front pads 152 of the semiconductor chip 100A1, adjacent to the base structure 300, may be directly bonded to the upper connection pads 354 to form the direct bonding DB1. The direct bonding DB1 may ensure electrical connection while bonding the base structure 300 and the semiconductor chip 100A1 to each other. An upper bonding insulating layer 364 may be formed on an upper surface of the base structure 300 according to the present example embodiment, and the upper bonding insulating layer 364 may have an upper surface, substantially planar with the upper connection pads 354. The upper bonding insulating layer 364 of the base structure 300 and the front insulating layer 162 of the lowermost semiconductor chip 100A1 may be directly bonded to each other to form the direct bonding DB2. As such, the base structure 300 and the lowermost semiconductor chip 100A1 may be hybrid-bonded to each other. For example, the upper bonding insulating layer 364 may include a first insulating film 364a and a second insulating film 364b, and the first insulating film 364a and the second insulating film 364b may be formed in substantially the same manner as the first insulating film 164a and the second insulating film 164b.

Due to at least one of the direct bonding DB1 and the direct bonding DB2, a conductive structure having a relatively low melting point, such as a bump or solder, may not be disposed between the plurality of semiconductor chips 100A1, 100A2, 100A3, and 100C. In general, the conductive structure (for example, a bump or solder) may be formed using a reflow process or a thermal compression bonding (TCB) process, but may require a minimum width or pitch (for example, a bump or solder) to secure reliability.

Due to at least one of the direct bonding DB1 and the direct bonding DB2, the plurality of semiconductor chips 100A1, 100A2, 100A3, and 100C may be bonded to each other without using the conductive structure (for example, a bump or solder), such that it may be advantageous to reduce a width or pitch of each of the plurality of front pads 152 and the plurality of rear pads 154. Accordingly, the plurality of semiconductor chips 100A1, 100A2, 100A3, and 100C may efficiently increase a degree of integration of the plurality of front pads 152 and the plurality of rear pads 154. As the degree of integration of the plurality of front pads 152 and the plurality of rear pads 154 increases, electrical paths (for example, paths through which at least one of a data signal, a control signal, and a power signal and a ground signal passes) of the plurality of semiconductor chips 100A1, 100A2, 100A3, and 100C may increase. Accordingly, the semiconductor packages 500 and 500A may be more advantageous for miniaturization and implementation of high performance. Alternatively, due to at least one of the direct bonding DB1 and direct bonding DB2, the electrical reliability (for example, impedance stability, reduction in equivalent series resistance, signal integrity, power integrity, or the like) between of the plurality of front pads 152 and the plurality of rear pads 154 may be further improved.

Due to at least one of the direct bonding DB1 and the direct bonding DB2, front surfaces and rear surfaces of the plurality of semiconductor chips 100A1, 100A2, 100A3, and 100C may be in direct contact with each other, such that it may be more important to flatten the front surfaces and rear surfaces. As the front surfaces and rear surfaces have higher flatness, the reliability (for example, poor contact or electrical short-circuit prevention performance) between the plurality of front pads 152 and the plurality of rear pads 154, and the reliability (for example, pore or crack prevention performance) between the front insulating layer 162b and rear insulating layer 164 may be improved.

The conductive pattern 147 may be disposed between the interconnection structure 140 and the plurality of front pads 152. The support insulating layer 162a may be disposed between the device layer 120 and the front insulating layer 162b to surround (be disposed around) the conductive pattern 147. Front surfaces (lower surfaces) and rear surfaces (upper surfaces) of the conductive pattern 147 and the support insulating layer 162a may be respectively coplanar with each other. A conductive pattern 347 and a support insulating layer 362 of the base structure 300 may be implemented in substantially the same manner as the conductive pattern 147 and the support insulating layer 162a.

When the plurality of front pads 152 are coupled to the plurality of rear pads 154 using an annealing process, not only the plurality of front pads 152 but also the conductive pattern 147 may be thermally expanded. The thermal expansion of the conductive pattern 147 may support the thermal expansion of the plurality of front pads 152 with respect to the plurality of rear pads 154. Accordingly, the plurality of front pads 152 and the plurality of rear pads 154 may be more efficiently coupled to each other. As the coupling efficiency between the plurality of front pads 152 and the plurality of rear pads 154 becomes higher, a minimum volume required for the plurality of front pads 152 and the plurality of rear pads 154 may be further reduced. Accordingly, the width or pitch of each of the plurality of front pads 152 and the plurality of rear pads 154 may be further refined, and a degree of integration of the electrical paths of the plurality of semiconductor chips 100A1, 100A2, 100A3, and 100C may also be further increased.

The support insulating layer 162a may be implemented in the same manner as the front insulating layer 162b. For example, the support insulating layer 162a may include at least one of SiO₂, SiN, SiCN, and tetraethyloxysilane (TEOS). The conductive pattern 147 may be implemented in the same manner (using the same material and the same process) as the interconnection layer 142 of the interconnection structure 140. Accordingly, the conductive pattern 147 may be a lowermost interconnection layer of the interconnection structure 140. For example, the conductive pattern 147 may include at least one of copper, a copper alloy, aluminum, and an aluminum alloy.

The conductive pattern 147 may have a thickness greater than a thickness of each of the plurality of interconnection layers 142. The conductive pattern 147, having the thickness greater than the thickness of each of the plurality of interconnection layers 142, may have a relatively large volume. As the conductive pattern 147 has a larger volume, the thermal expansion of the plurality of front pads 152 with respect to the plurality of rear pads 154 may be efficiently stably supported.

Depending on the design, the conductive pattern 147 may include a conductive material (for example, aluminum) having a thermal expansion coefficient, higher than that of a conductive material (for example, copper) of the plurality of front pads 152. A thermal expansion coefficient of aluminum may be higher than that of copper, and thus the conductive pattern 147, including aluminum, may more efficiently support the thermal expansion of the plurality of front pads 152 including copper.

The efficiency with which the conductive pattern 147 supports the thermal expansion coupling between the plurality of front pads 152 and the plurality of rear pads 154 may be a trade-off with the flatness (or importance of flatness) of front surfaces of the plurality of semiconductor chips 100A1, 100A2, 100A3, and 100C. The semiconductor package 500 or 500A according to one or more example embodiments of the disclosure may secure one of the thermal expansion coupling support efficiency and the flatness (or importance of flatness) while improving the other one.

Referring to FIGS. 1 and 3A, the conductive pattern 147 may include a plurality of pad patterns 147a electrically connected between the interconnection structure 140 and the plurality of front pads 152, and dummy patterns 147b and 147c spaced apart from the plurality of front pads 152 and the plurality of pad patterns 147a.

For example, a front surface (lower surface) and a rear surface (upper surface) of each of the plurality of pad patterns 147a may have a polygonal shape or circular shape. A width (X1 or Y1) of each of the plurality of pad patterns 147a may be wider than a width of each of the plurality of front pads 152. Accordingly, the plurality of pad patterns 147a may more stably support the plurality of front pads 152.

For example, portions (for example, central portions) of the front surfaces (lower surfaces) of the plurality of pad patterns 147a may be in direct contact with the plurality of front pads 152, and other portions (for example, edge portions) of the front surfaces of the plurality of pad patterns 147a may be in direct contact with the front insulating layer 162b. Accordingly, the overall stacking stability of a combination 162 of the support insulating layer 162a and the front insulating layer 162b may be improved, thereby stably preventing the occurrence of delamination of the combination 162.

The dummy patterns 147b and 147c may fill portions of peripheral spaces of the plurality of pad patterns 147a so as to prevent a metal material from concentrating at specific points (for example, the plurality of pad patterns 147a) of the combination of the conductive pattern 147 and the support insulating layer 162a. Accordingly, even when the conductive pattern 147 is thicker than the interconnection layer 142, the combination of the conductive pattern 147 and the support insulating layer 162a may be stably stacked on a front surface (lower surface) of the device layer 120, and the occurrence of delamination of the combination may be stably prevented. That is, the dummy patterns 147b and 147c may improve the structural stability of the conductive pattern 147 and the periphery thereof.

The dummy patterns 147b and 147c may be spaced apart from the plurality of pad patterns 147a, and may not be connected to the plurality of front pads 152 and/or the interconnection structure 140. For example, the plurality of pad patterns 147a may be configured to transmit a signal to the interconnection structure 140 or receive a signal from the interconnection structure 140, and the dummy patterns 147b and 147c may have a ground or DC voltage. The dummy patterns 147b and 147c may surround (be disposed around) the plurality of pad patterns 147a, thereby electromagnetically shielding the plurality of pad patterns 147a. In addition, a relatively large volume of the dummy patterns 147b and 147c may improve the electrical stability of a DC voltage or ground.

A total area (for example, an area based on X1, X3, and Y3) of the dummy patterns 147b and 147c may be larger than a total area of the plurality of pad patterns 147a (for example, an area based on X1 and Y1). As the total area of the dummy patterns 147b and 147c increases, the dummy patterns 147b and 147c may further improve the structural stability (for example, prevention of delamination) of the conductive pattern 147 and the peripheral thereof.

In general, as the connectivity (or the total number of dummy patterns relative to a unit area) between portions of the dummy patterns 147b and 147c increases, the total area of the dummy patterns 147b and 147c may be more efficiently increased. However, as the connectivity between the portions of the dummy patterns 147b and 147c (or the total number of dummy patterns relative to a unit area) increases, the effect of the thermal expansion of the dummy patterns 147b and 147c on the flatness (or importance of flatness) of the front surfaces of the plurality of semiconductor chips 100A1, 100A2, 100A3, and 100C may increase. Accordingly, the structural stability (for example, prevention of delamination) of the conductive pattern 147 and the periphery thereof may be a trade-off with the flatness (or importance of flatness). The semiconductor packages 500 and 500A according to one or more example embodiments of the disclosure may secure one of the structural stability and the flatness while improving the other one.

Referring to FIG. 3A, the dummy patterns 147b and 147c may include a plurality of first dummy patterns 147c disposed between the plurality of pad patterns 147a to overlap the plurality of pad patterns 147a in a first direction (for example, the horizontal X direction in FIG. 3A), rather than in a second direction (for example, the vertical Y direction in FIG. 3A), and a plurality of second dummy patterns 147b disposed between the plurality of first dummy patterns 147c to overlap the plurality of pad patterns 147a in the second direction (for example, the vertical direction in FIG. 3A), rather than in the first direction (for example, the horizontal direction in FIG. 3A). The center of a front surface (lower surface in FIG. 1) of each of the plurality of first dummy patterns 147c may be in direct contact with the front insulating layer 162b or the rear insulating layer 164, and the center of a front surface (lower surface in FIG. 1) of each of the plurality of second dummy patterns 147b may be in direct contact with the front insulating layer 162b or the rear insulating layer 164.

The plurality of first dummy patterns 147c and the plurality of second dummy patterns 147b may overlap the plurality of pad patterns 147a in the first and second directions, respectively, such that the dummy patterns 147b and 147c may effectively prevent a metal material from concentrating at specific points (for example, the plurality of pad patterns 147a) of the combination of the conductive pattern 147 and the support insulating layer 162a. Accordingly, the structural stability (for example, prevention of delamination) of the conductive pattern 147 and the periphery thereof may be efficiently improved.

The plurality of first dummy patterns 147c may thermally expand in the first direction, and the plurality of second dummy patterns 147b may thermally expand in the first and second directions. In this case, the thermal expansion of the plurality of first dummy patterns 147c in the first direction and the thermal expansion of the plurality of second dummy patterns 147b in the first direction may be converged between the plurality of first dummy patterns 147c and the plurality of second dummy patterns 147b. Such convergence of thermal expansion may be derived from a thermal expansion phenomenon in a direction (for example, the vertical direction in FIG. 1), perpendicular to the first and second directions, and may be a factor interfering with the flatness of the front surfaces of the plurality of semiconductor chips 100A1, 100A2, 100A3, and 100C.

The plurality of second dummy patterns 147b may be spaced apart from the plurality of first dummy patterns 147c. Accordingly, a space between the plurality of first dummy patterns 147c and the plurality of second dummy patterns 147b may be a spare space preventing the convergence of thermal expansion from being a factor interfering with the flatness. Accordingly, the flatness of the front surfaced of the plurality of semiconductor chips 100A1, 100A2, 100A3, and 100C may be stably secured.

Alternatively, the plurality of first dummy patterns 147c may extend in the second direction (for example, the vertical direction in FIG. 3A), and may be spaced apart from each other in the first direction (for example, the horizontal direction in FIG. 3A) between two adjacent pad patterns, among the plurality of pad patterns 147a. For example, when six pad patterns 147a are arranged in the first direction (for example, the horizontal direction in FIG. 3A), two or more first dummy patterns 147c may be disposed per space between five pad patterns 147a, and a total of ten or more dummy patterns 147c may be disposed.

A space SL1 between the plurality of first dummy patterns 147c in a space between two adjacent pad patterns, among the plurality of pad patterns 147a, may be a spare space, preventing the convergence of thermal expansion from being a factor interfering with the flatness. Accordingly, the flatness of the front surfaces of the plurality of semiconductor chips 100A1, 100A2, 100A3, and 100C may be stably secured.

Alternatively, the dummy patterns 147b and 147c may include a plurality of dummy patterns 147b and 147c each having a form in which an extension direction (for example, the vertical direction in FIG. 3A) is not bent or not extended, the plurality of dummy patterns 147b and 147c arranged to surround (be disposed around) each of the plurality of pad patterns 147a.

The plurality of dummy patterns 147b and 147c may surround (be disposed around) each of the plurality of pad patterns 147a, such that a portion of a space around the plurality of pad patterns 147a may be efficiently filled, thereby effectively improving the structural stability (for example, prevention of delamination) of the conductive pattern 147 and the periphery thereof.

A form in which the extension direction (for example, the vertical direction in FIG. 3A) is bent may cause thermal expansion convergence at a point at which the extension direction (for example, the vertical direction in FIG. 3A) is bent, and the thermal expansion convergence may be derived from a thermal expansion phenomenon in a direction (for example, the vertical direction in FIG. 1), perpendicular to the first and second directions. Each of the plurality of dummy patterns 147b and 147c may have a form in which the extension direction (for example, the vertical direction in FIG. 3A) is not bent or not extended, thereby preventing the thermal expansion convergence at the point at which the extension direction is bent. Accordingly, the flatness of the front surfaces of the plurality of semiconductor chips 100A1, 100A2, 100A3, and 100C may be stably secured.

For example, each of the plurality of first dummy patterns 147c may extend in the second direction (for example, the vertical direction in FIG. 3A), and a portion of each of the plurality of first dummy patterns 147c may overlap the plurality of second dummy patterns 147b in the first direction (for example, the horizontal direction in FIG. 3A). Accordingly, an area of each of the plurality of first dummy patterns 147c may be efficiently increased, such that the structural stability of the conductive pattern 147 (and/or the periphery thereof) and the electrical stability of a DC voltage or ground may be efficiently improved. In addition, the plurality of first dummy patterns 147c may have an efficient structure (for example, a structure extending in the second direction) for connection to the DC voltage or ground.

For example, each of the plurality of second dummy patterns 147b may have a shape the same as that of each of the plurality of pad patterns 147a, and n second dummy patterns 147b and n pad patterns 147a (for example, n=1) may be alternately arranged in the second direction (for example, the vertical direction in FIG. 3A). Accordingly, the structural stability of a space in which the plurality of second dummy patterns 147b and the plurality of pad patterns 147a are alternately arranged may be efficiently improved.

In terms of the overall dummy patterns 147b and 147c, the plurality of first dummy patterns 147c may have a continent shape and the plurality of second dummy patterns 147b may have an island shape. For example, a gap X2 between the plurality of first dummy patterns 147c and the plurality of second dummy patterns 147b may be longer than a gap Y2 between the plurality of second dummy patterns 147b and the plurality of pad patterns 147a, and may be longer than a gap X4 between the plurality of first dummy patterns 147c. For example, a width X3 of each of the plurality of first dummy patterns 147c may be longer than the gaps X2 and X4. For example, widths X1 and Y3 of each of the plurality of second dummy patterns 147b and widths X1 and Y1 of each of the plurality of pad patterns 147a may be longer than the width X3 of each of the plurality of first dummy patterns 147c. Here, the widths X1, Y1, and Y3 may be measured in the first direction or the second direction relative to the center of each of corresponding patterns.

Each of X1, X2, X3, X4, Y1, Y2, and Y3 may be measured as an average value in a horizontal cross-section of a semiconductor package and may be applied to analysis using at least one of a transmission electron microscope (TEM), an atomic force microscope (AFM), a scanning electron microscope (SEM), an optical microscope, and a surface profiler. Each of X1, X2, X3, X4, Y1, Y2, and Y3 may be measured using visual inspection or image processing (for example, identification of pixels based on color or brightness of the pixels, filtering pixel values for pixel identification efficiency, integration of a distance between identified pixels, or the like).

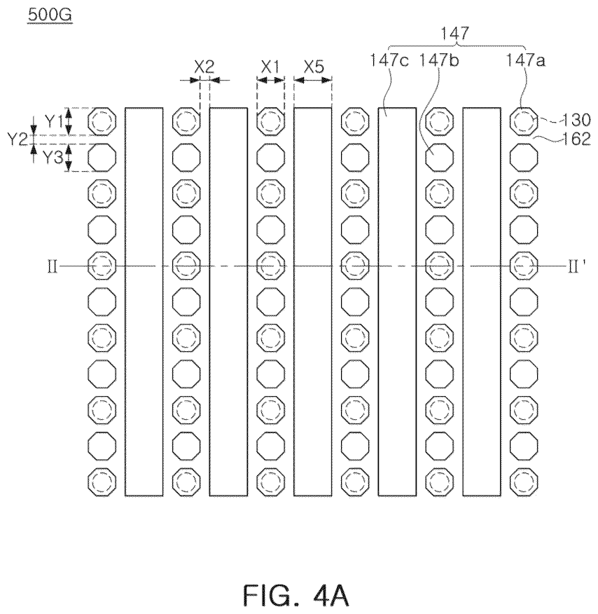

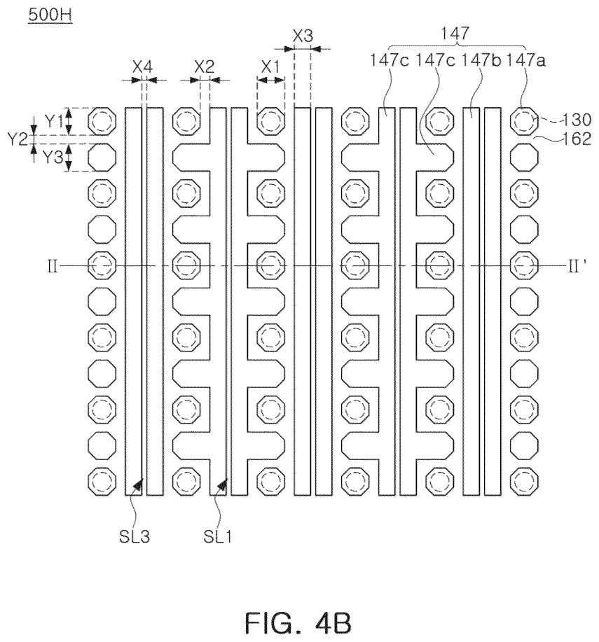

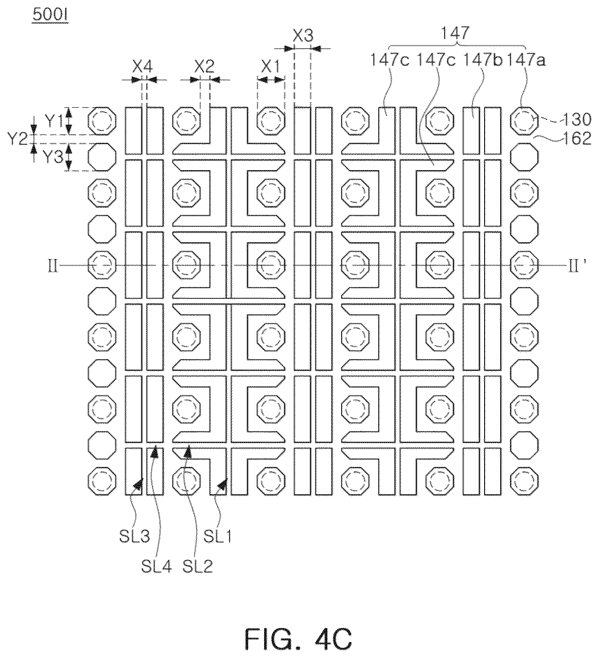

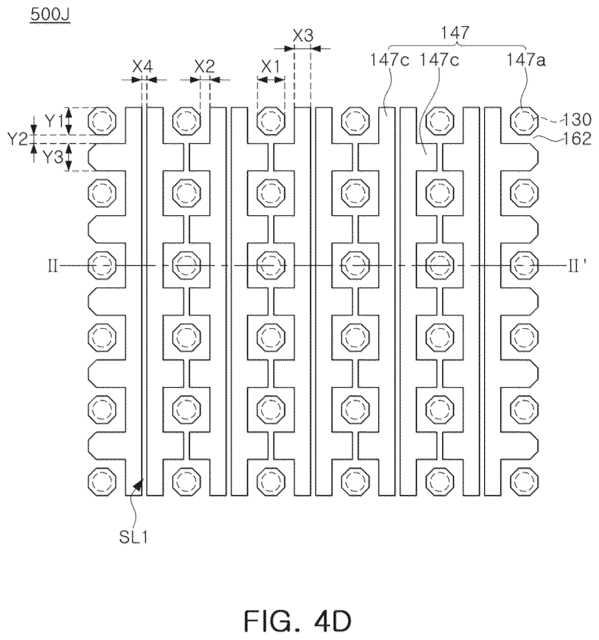

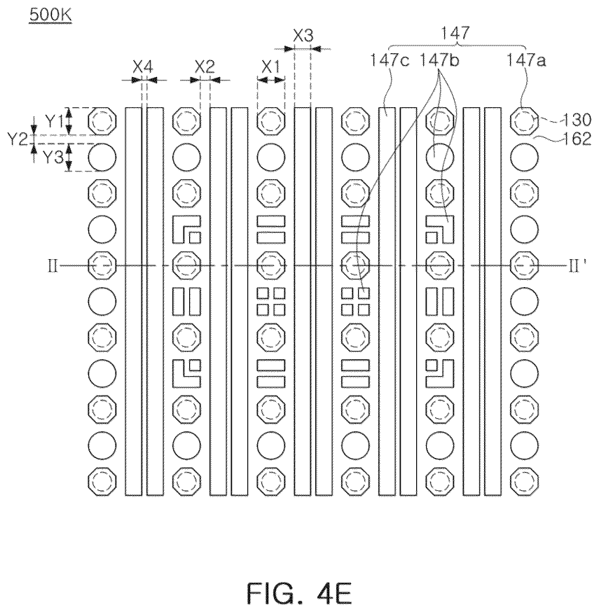

A structure of the conductive pattern 147 of the semiconductor package 500 according to one or more example embodiments of the disclosure is not limited to the structure of the conductive pattern 147 illustrated in FIG. 3A, and may be one of various structures of the conductive pattern 147 illustrated in FIGS. 3B to 4E, or a combination thereof. Referring to FIGS. 3A, 3B, 3C, 3D, 3E, 3F, 4A, and 4E, the dummy patterns 147b and 147c may include a plurality of first dummy patterns 147c disposed between the plurality of pad patterns 147a to overlap the plurality of pad patterns 147a in the first direction (for example, the horizontal direction in FIG. 3A), rather than in the second direction (for example, the vertical direction in FIG. 3A), and a plurality of second dummy patterns 147b disposed between the plurality of first dummy patterns 147c to overlap the plurality of pad patterns 147a in the second direction (for example, the vertical direction in FIG. 3A), rather than in the first direction (for example, the horizontal direction in FIG. 3A). The plurality of second dummy patterns 147b may be spaced apart from the plurality of first dummy patterns 147c.

In addition, referring to FIGS. 3A, 3B, 3C, 3D, 3E, 3F, 4B, 4C, 4D, and 4E, the plurality of first dummy patterns 147c may extend in the second direction (for example, the vertical direction in FIG. 3A), and may be spaced apart from each other in the first direction (for example, the horizontal direction in FIG. 3A) between two adjacent pad patterns, among the plurality of pad patterns 147a. Referring to FIGS. 3A, 3B, 3C, 3D, 3E, 3F, 4A, and 4E, the dummy patterns 147b and 147c may include a plurality of dummy patterns 147b and 147c each having a form in which an extension direction (for example, the vertical direction in FIG. 3A) is not bent or not extended, the plurality of dummy patterns 147b and 147c arranged to surround (be disposed around) each of the plurality of pad patterns 147a.

Referring to FIG. 3B, a semiconductor package 500B according to one or more example embodiments of the disclosure may have a structure in which some first dummy patterns, among a plurality of first dummy patterns 147c, overlap each other in a second direction (for example, a vertical direction). The plurality of first dummy patterns 147c may have a space SL1 in a first direction and a space SL2 in a second direction together. The number of spaces SL2 in the second direction is not limited to the structure illustrated in FIG. 3B, and an area of each of the plurality of first dummy patterns 147c may be adjusted by adjusting the number of spaces SL2 in the second direction.

Referring to FIGS. 3C to 3F, semiconductor packages 500C, 500D, 500E, and 500F according to one or more example embodiments of the disclosure may have a structure in which a shape of each of a plurality of second dummy patterns 147b is different from a shape (for example, a polygonal shape) of each of a plurality of pad patterns 147a. Referring to FIG. 3C, the shape of each of the plurality of second dummy patterns 147b may be a circular shape.

Referring to FIGS. 3D to 3F, semiconductor packages 500D, 500E, and 500F according to one or more example embodiments of the disclosure may have a structure in which an area of each of a plurality of second dummy patterns 147b is smaller than an area of each of a plurality of pad patterns 147a, and a structure in which some second dummy patterns, among the plurality of second dummy patterns 147b, are spaced apart from each other between two adjacent pad patterns, among the plurality of pad patterns 147a. Referring to FIG. 3D, the plurality of second dummy patterns 147b may be spaced apart from each other in a first direction (for example, a horizontal direction), may extend in a second direction (for example, a vertical direction), and may have a space SL3 between the plurality of second dummy patterns 147b. Referring to FIG. 3E, the plurality of second dummy patterns 147b may be spaced apart from each other in the second direction (for example, a vertical direction), may extend in the first direction (for example, a horizontal direction), and may have a space SL4 between the plurality of second dummy patterns 147b. Referring to FIG. 3F, the plurality of second dummy patterns 147b may be spaced apart from each other in first and second directions (for example, horizontal and vertical directions), and may have spaces SL3 and SL4 between the plurality of second dummy patterns 147b.

Referring to FIG. 4A, a plurality of first dummy patterns 147c of a semiconductor package 500G according to one or more example embodiments of the disclosure may extend in a second direction (for example, a vertical direction), and may be implemented as one pad pattern between two adjacent pad patterns, among a plurality of pad patterns 147a. Accordingly, the plurality of first dummy patterns 147c each may have a wider width X5, but may be spaced apart from a plurality of second dummy patterns 147b in a first direction (for example, a horizontal direction).

Referring to FIGS. 4B to 4D, a plurality of first dummy patterns 147c of semiconductor packages 500H, 500I, and 500J according to one or more example embodiments of the disclosure may overlap a plurality of pad patterns 147a in first and second directions (for example, horizontal and vertical directions). Here, the plurality of first dummy patterns 147c may extend in the second direction (for example, a vertical direction), and may be spaced apart from each other in the first direction (for example, a horizontal direction) between two adjacent pad patterns, among the plurality of pad patterns 147a. A space SL1 between the plurality of first dummy patterns 147c may be a spare space, reducing the effect of thermal expansion of a conductive pattern 147 on the flatness of front surfaces of a plurality of semiconductor chips.

Referring to FIGS. 4B and 4C, a plurality of second dummy patterns 147b may overlap the plurality of pad patterns 147a in the first direction (for example, a horizontal direction), rather than in the second direction (for example, a vertical direction). Referring to FIG. 4D, the conductive pattern 147 may not include the plurality of second dummy patterns.

Referring to FIG. 4E, a plurality of second dummy patterns 147b of a semiconductor package 500K according to one or more example embodiments of the disclosure may have different shapes. For example, the plurality of second dummy patterns 147b may have a more finely divided structure as a distance from the center of the semiconductor package 500K decreases, and each of the plurality of second dummy patterns 147b may have a larger area as a distance from an edge of the semiconductor package 500K decreases.

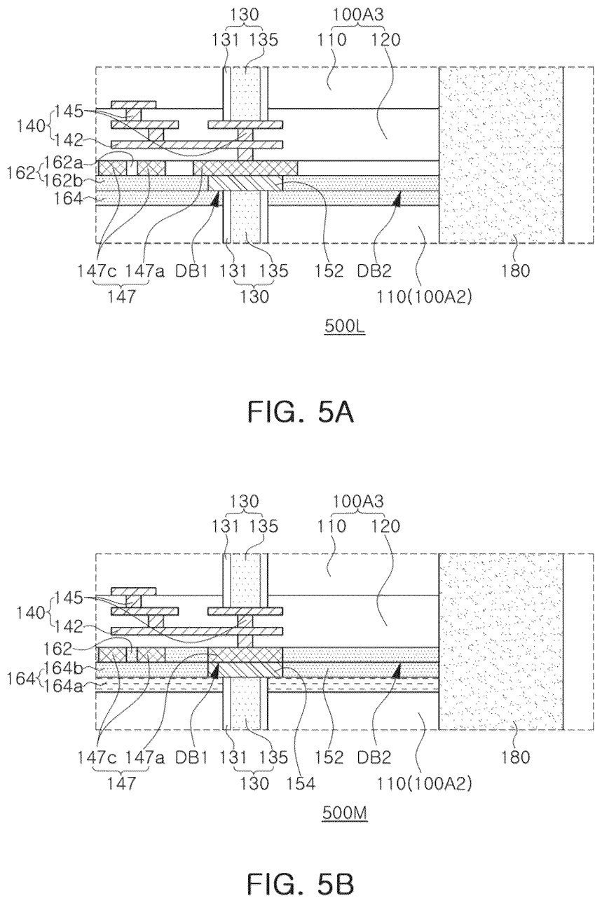

FIGS. 5A and 5B illustrate enlarged portions of semiconductor packages 500L and 500M according to one or more example embodiments of the disclosure, and the portions may correspond to portion B of FIG. 1, but may also be implemented in portion A of FIG. 1.

Referring to FIG. 5A, the semiconductor package 500L according to one or more example embodiments of the disclosure may have a structure in which the rear pad 154 of FIG. 2B is omitted, and may have a structure in which a front pad 152 and a through-electrode 130 are in direct contact with each other. The conductive pattern 147 illustrated in FIGS. 3A to 4E may support direct bonding DB1 between the front pad 152 and the through-electrode 130, and may secure flatness between the front pad 152 and the through-electrode 130.

Referring to FIG. 5B, the semiconductor package 500M according to one or more example embodiments of the disclosure may have a structure in which the front pad 152 of FIG. 2B is omitted, and may have a structure in which a plurality of pad patterns 147a of a conductive pattern 147 and a plurality of rear pads 154 are in direct contact with each other. For example, an area of the plurality of pad patterns 147a may be adjusted to correspond to an area of the plurality of rear pads 154, and a conductive material (for example, copper) included in the plurality of pad patterns 147a may also correspond to a conductive material (for example, copper) included in the plurality of rear pads 154. The plurality of pad patterns 147a may be surrounded by a combination 162 of a support insulating layer and a front insulating layer, and the support insulating layer may be omitted from the combination 162. The conductive pattern 147 illustrated in FIGS. 3A to 4E may improve the stability of direct bonding DB1 between the plurality of pad patterns 147a and the plurality of rear pads 154, and may secure flatness between the plurality of pad patterns 147a and the plurality of rear pads 154.

Referring to FIG. 1, the semiconductor package 500 according to one or more example embodiments of the disclosure may include an upper dummy chip 200 disposed on a rear surface (upper surface) of the semiconductor chip 100C. For example, the upper dummy chip 200 may include a semiconductor such as silicon or a substrate such as metal. In some example embodiments, the upper dummy chip 200 may provide a heat dissipation function and/or an identification mark display region.

The upper dummy chip 200 may have a thickness T2, greater than a thickness T1a of the plurality of semiconductor chips 100A1, 100A2, and 100A3 and a thickness T1b of the semiconductor chip 100C. For example, the thickness T2 of the upper dummy chip 200 may be 200 μm or more, and the thicknesses T1a and T1b may be 100 μm or less.

The upper dummy chip 200 may include a lower bonding insulating layer 210 disposed on a lower surface thereof, and the semiconductor chip 100C may include a rear insulating layer 174 disposed on an upper surface thereof. The lower bonding insulating layer 210 and the rear insulating layer 174 may be directly bonded to each other, such that the upper dummy chip 200 may be bonded to a rear surface (upper surface) of the semiconductor chip 100C. As such, the upper dummy chip 200 and the semiconductor chip 100C may be bonded to each other through inter-dielectric bonding between the lower bonding insulating layer 210 and the rear insulating layer 174. At least one of the lower bonding insulating layer 210 and the rear insulating layer 174 may include a dielectric layer formed using a deposition process. Alternatively, the at least one may include a natural oxide film formed using a high-temperature annealing process.

A width W2 (that is, an area) of the upper dummy chip 200 may be the same as a width W1a (that is, an area) of the plurality of semiconductor chips 100A1, 100A2, and 100A3, and may be the same as a width W1b (that is, an area) of the semiconductor chip 100C, but the disclosure is not limited thereto.

Referring to FIG. 1, the semiconductor package 500 according to one or more example embodiments of the disclosure may include a molding portion 180 sealing the plurality of semiconductor chips 100A1, 100A2, 100A3, and 100C and the upper dummy chip 200. For example, the molding portion 180 may include an epoxy mold compound (EMC) or the like.

An upper surface 200T of the upper dummy chip 200 may be exposed to an upper surface 180T of the molding portion 180. The exposed upper surface 200T of the upper dummy chip 200 may be substantially coplanar with the upper surface 180T of the molding portion 180. The upper surfaces, coplanar with each other, may be understood as upper surfaces obtained using a polishing process. In addition, a side surface of the molding portion 180 may be substantially coplanar with a side surface of the base structure 300. The side surfaces, coplanar with each other, may be understood as side surfaces obtained using the same cutting process.

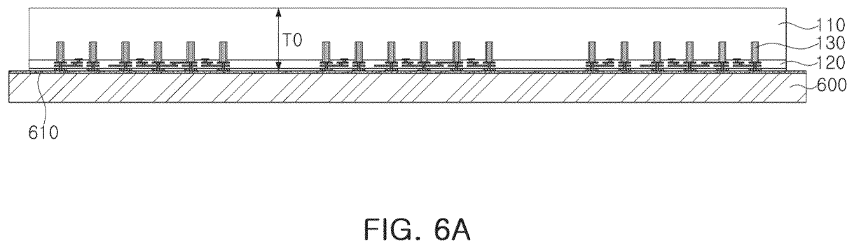

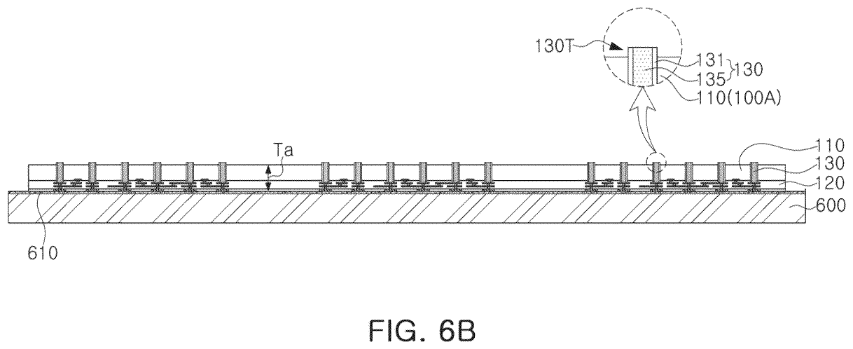

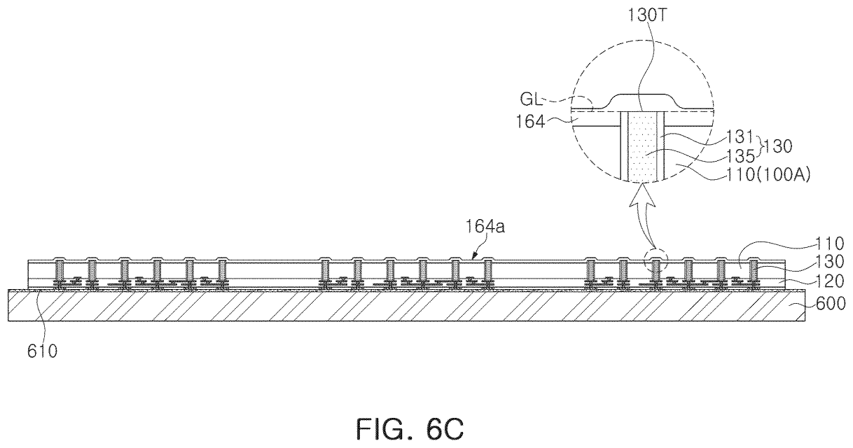

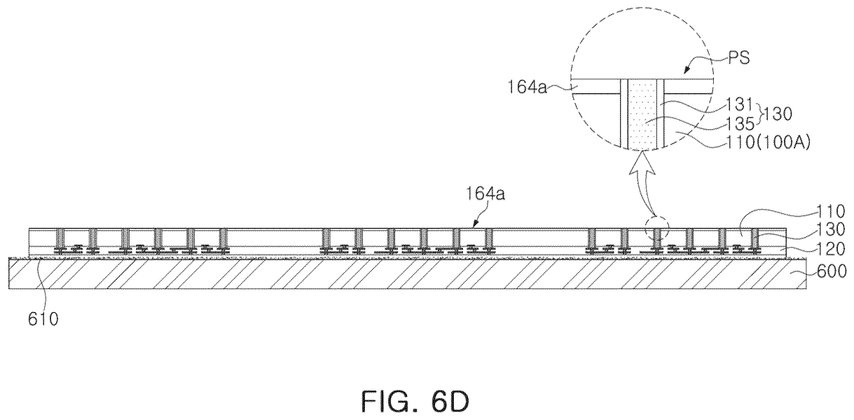

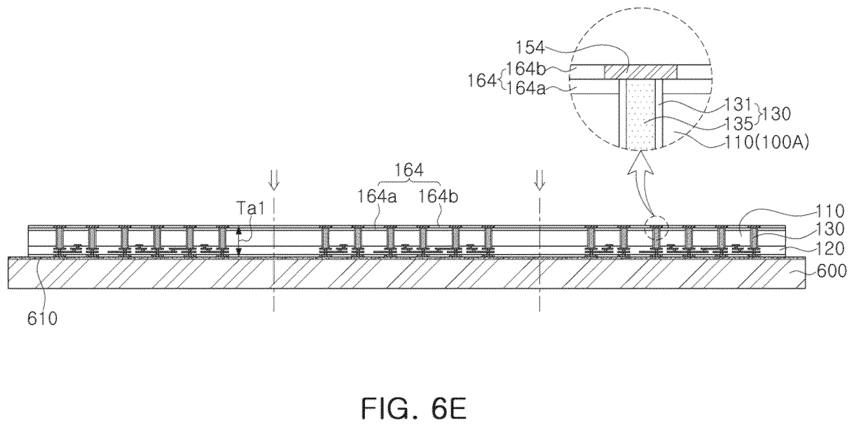

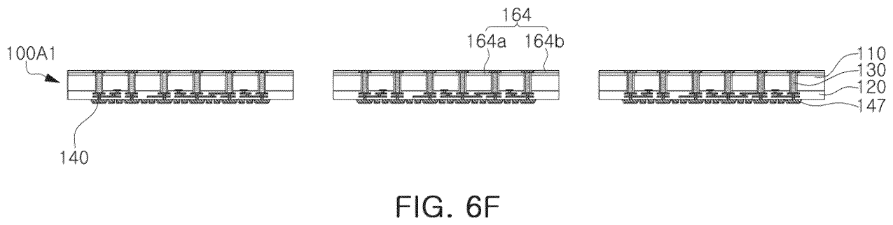

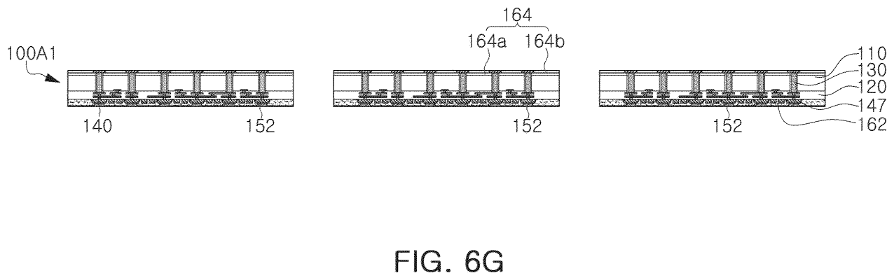

Referring to FIGS. 6A to 6E, a method of manufacturing a semiconductor package according to one or more example embodiments of the disclosure may include an operation of forming a device layer 120, a semiconductor substrate 110, a rear insulating layer 164, and a plurality of rear pads 154.

Referring to FIG. 6A, a semiconductor substrate 110 for a plurality of semiconductor chips 100A may be bonded to a carrier substrate 600. For ease of description, the semiconductor substrate 110 is illustrated as a wafer including three semiconductor chips 100A. Individual elements may form the plurality of semiconductor chips on an active surface of the semiconductor substrate 110. In addition, through-electrodes 130 extending into the semiconductor substrate 110, and a device layer 120 connected to the through-electrodes 130 and formed on the active surface of the semiconductor substrate 110. As such, it may be understood that the semiconductor substrate 110 is in a state in which a backside process is not performed after a front process of a semiconductor chip is completed. That is, the semiconductor substrate 110 may be in a state in which a grinding process is not applied, and thus the semiconductor substrate 110 may have a relatively large first thickness T0. A front surface (lower surface) of the semiconductor substrate 110, that is, a surface on which the device layer is formed, may be bonded to oppose the carrier substrate 600. Such bonding may be implemented using an adhesive layer 610 such as a UV curable film.

Referring to FIG. 6B, the grinding process may be applied to an inactive surface of the semiconductor substrate 110 such that the thickness of the semiconductor substrate 110 is reduced from T0 to Ta. In the grinding process, an upper end 130T of the through-electrode 130 may be exposed from a ground surface of a semiconductor wafer. Due to a difference in etch rates, the semiconductor wafer 100 may protrude from the surface. A thickness of the semiconductor chip 100A may be reduced to a desired thickness Ta using the present process. Such a process of reducing a thickness may be performed using an etch-rear process, in addition to a grinding process such as a chemical mechanical polishing (CMP) process, or a combination thereof. In some example embodiments, the grinding process may be performed to reduce the thickness of the semiconductor substrate 110, and the etch-rear process may be performed under appropriate conditions to sufficiently expose the through-electrode 130.

Referring to FIG. 6C, a first insulating film 164a may be formed on the semiconductor substrate 110 to cover the exposed upper end 130T of the through-electrode 130. The first insulating film 164a may be used as a passivation layer. For example, the first insulating film 164a may include silicon nitride or silicon oxynitride.

Referring to FIG. 6D, the first insulating film 164a may be ground to expose the through-electrode 130. The grinding process may be performed up to a predetermined line GL such that the first insulating film 164a is partially removed and the through-electrode 130 is sufficiently exposed. The first insulating film 164a may have a upper surface, substantially planar with an upper surface of the through-electrode 130, using the grinding process. In addition, a damaged portion of the upper end 130T of the through-electrode 130 may also be removed.

Referring to FIG. 6E, a plurality of rear pads 154 and a second insulating film 164b, surrounding (being disposed around) the plurality of rear pads 154, may be formed on the first insulating film 164a. In a similar manner to the above-described processes, the plurality of rear pads 154 may be formed on the first insulating film 164a, and the second insulating film 164b may be formed to cover the plurality of rear pads 154. Subsequently, the grinding process may be performed such that the second insulating film 164b is partially removed to expose rear surfaces (upper surfaces) of the plurality of rear pads 154. The second insulating film 164b may have a rear surface (upper surface), substantially planar with the rear surfaces (upper surfaces) of the plurality of rear pads 154, using the grinding process. For example, the second insulating film 164b may include silicon oxide. As used herein, the first and second insulating films 164a and 164b are collectively referred to as a rear insulating layer 164.

Referring to FIG. 6F, the method of manufacturing a semiconductor package according to one or more example embodiments of the disclosure may include an operation of forming a conductive pattern 147 on a front surface (lower surface) of a device layer 120 of at least one 100A1 of the plurality of semiconductor chips. For example, the conductive pattern 147 may be formed using photolithography. FIG. 6F illustrates the conductive pattern 147 formed after the semiconductor substrate 110, the rear insulating layer 164, and the plurality of rear pads 154 are formed. However, depending on the design, the conductive pattern 147 may also be formed together with the device layer 120. This is because the conductive pattern 147 may be a portion of an interconnection structure 140 of the device layer 120. That is, the operation of forming the conductive pattern 147 on the front surface (lower surface) of the device layer 120 of the at least one 100A1 of the plurality of semiconductor chips may be a portion of the operation of forming the device layer 120.

Referring to FIG. 6G, the method of manufacturing a semiconductor package according to one or more example embodiments of the disclosure may include an operation of forming a plurality of front pads 152 by forming a combination 162 of a support insulating layer 162a and a front insulating layer 162b. For example, the operation may further include an operation of flattening a front surface (lower surface) of the support insulating layer 162a after the support insulating layer 162a is formed, and the front insulating layer 162b may be formed after the support insulating layer 162a is flattened. For example, the operation may further include an operation of forming holes in the front insulating layer 162b, and the plurality of front pads 152 may be formed to fill the holes. Depending on the design, the operation may also be performed before the semiconductor substrate 110, the rear insulating layer 164, and the plurality of rear pads 154 are formed.

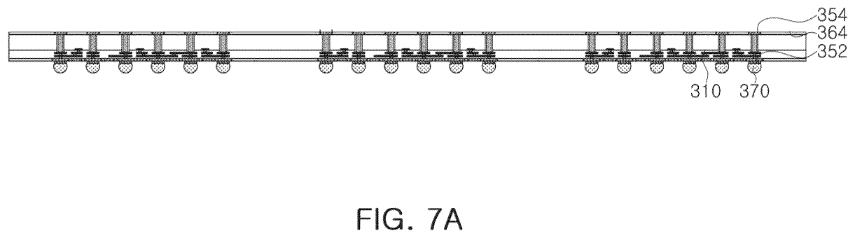

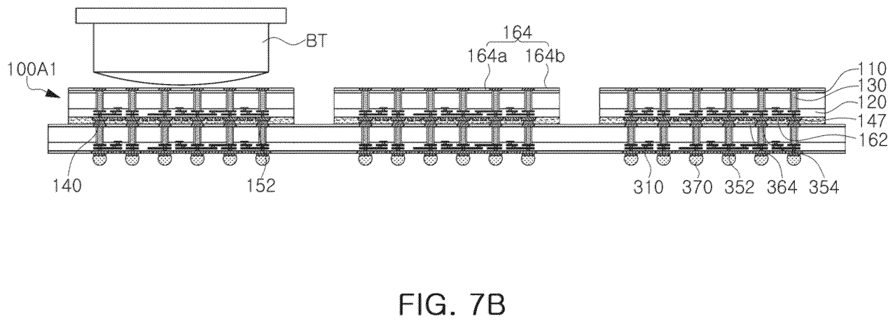

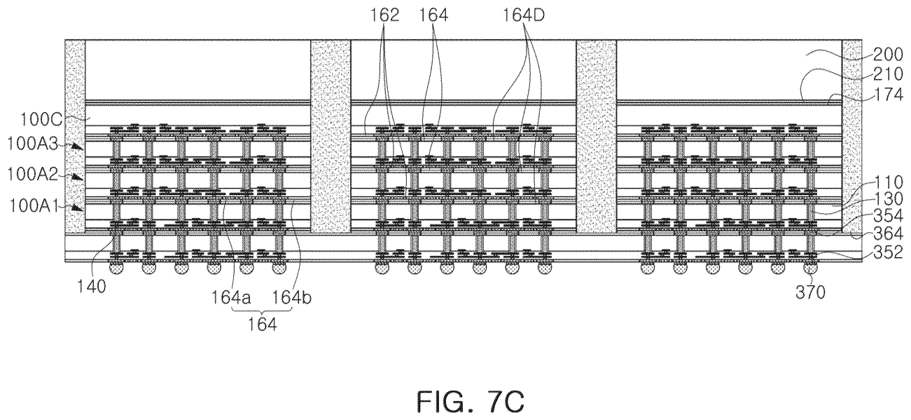

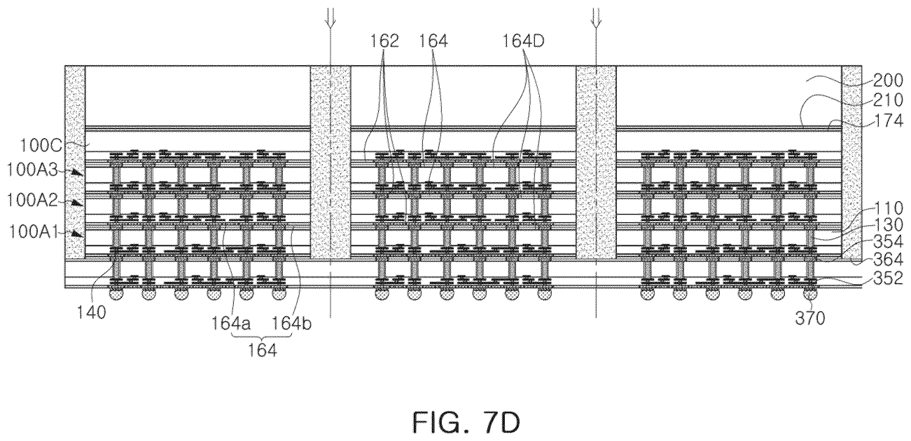

Referring to FIGS. 7A to 7D, a method of manufacturing a semiconductor package according to one or more example embodiments of the disclosure may include an operation of directly bonding a combination 162 of a support insulating layer 162a and a front insulating layer 162b of one of plurality of semiconductor chips 100A1, 100A2, 100A3, and 100C to a rear insulating layer 164 of another one of the plurality of semiconductor chips 100A1, 100A2, 100A3, and 100C.

Referring to FIG. 7A, a base structure 300W having upper connection pads 354 and lower connection pads 352 may be prepared. For ease of description, it is illustrated that the base structure 300W is in a form for manufacturing three semiconductor packages. The base structure 300W may include an upper bonding insulating layer 364, surrounding (being disposed around) upper connection pads 354, on an upper surface thereof. The upper bonding insulating layer 364 may have an upper surface, substantially coplanar with upper surfaces of the upper connection pads 354. A connection bump 370, such as a solder ball, may be formed on the lower connection pads 352 of the base structure 300W. In addition, in the present example embodiment, it is illustrated that the base structure 300W is in the form of a logic chip or a memory chip, electrically connecting the upper connection pads 354 and the lower connection pads 352, is implemented. However, depending on the design, the base structure 300W may be an interposer having an internal circuit.

Referring to FIG. 7B, individualized semiconductor chips 100A1 may be disposed on the base structure 300W. The semiconductor chip 100A1 may be a semiconductor chip obtained in the operation illustrated in FIG. 6G. In the present stacking process, pre-bonding may be performed by applying a certain pressure using a bonding tool BT. Specifically, a plurality of front pads 152 of first semiconductor chips 100A1 each may be directly pre-bonded to the upper connection pads 354 of the base structure 300. Similarly, a front insulating layer 162 of the semiconductor chips 100A1 may be directly pre-bonded to the upper bonding insulating layer 364 of the base structure 300.

Referring to FIG. 7C, additional semiconductor chips 100A2 and 100A3 may be sequentially stacked, and a semiconductor chip 100C may be disposed on uppermost semiconductor chips 100A3. A plurality of semiconductor chips 100A2, 100A3, and 100C may be pre-bonded to other semiconductor chips 100A1, 100A2, and 100A3 positioned therebelow. Specifically, a plurality of front pads 152 and a front insulating layer 162 of each of semiconductor chips 100A2, 100A3, and 100C may be directly pre-bonded to a plurality of rear pads 154 and a rear insulating layer 164 of each of other semiconductor chips 100A1, 100A2, and 100A3 stacked immediately therebefore, respectively. Thereafter, an annealing process may be performed, the front insulating layer 162 and the rear insulating layer 164 may be directly bonded to each other, and the plurality of front pads 152 and the plurality of ear pads 154 may be directly bonded to each other. Thereafter, an upper dummy chip 200 may be disposed on a rear surface (upper surface) of the semiconductor chip 100C, and a rear surface (upper surface) of the upper dummy chip 200 may be polished.

Referring to FIG. 7D, the semiconductor package illustrated in FIG. 7C may be cut in a vertical direction. Accordingly, a plurality of semiconductor packages may be formed. Depending on the design, the rear surface (upper surface) of the upper dummy chip 200 may include an identification mark or provide a space for disposing a heat sink.

As set forth above, a semiconductor package according to one or more example embodiments of the disclosure may improve electrical properties and/or reliability of a front surface of a semiconductor chip. For example, the semiconductor package may increase a degree of integration of electrical connection paths (for example, pads) between a plurality of semiconductor chips, or may improve electrical properties (for example, signal integrity) of the electrical connection paths (for example, pads), and may improve the reliability (for example, the flatness of a surface, the structural stability of a layer, and delamination prevention performance) between the plurality of semiconductor chips.

While example embodiments have been illustrated and described above, it will be apparent to those skilled in the art that modifications and variations could be made without departing from the scope of the disclosure as defined by the appended claims.

What is claimed is:

1. A semiconductor package comprising:
a plurality of semiconductor chips, each of the plurality of semiconductor chips comprising at least one of a front insulating layer and a rear insulating layer, adjacent semiconductor chips of the plurality of semiconductor chips being bonded to each other through direct bonding between the front insulating layer of a first one of the adjacent semiconductor chips and the rear insulating layer of a second one of the adjacent semiconductor chips,
wherein at least one of the plurality of semiconductor chips comprises:
a device layer comprising an interconnection structure; and
a conductive pattern on a front surface of the device layer,
wherein the conductive pattern comprises:
a plurality of pad patterns electrically connected to the interconnection structure; and
a dummy pattern spaced apart from the plurality of pad patterns,
wherein the dummy pattern comprises:
a plurality of first dummy patterns between the plurality of pad patterns and overlapping the plurality of pad patterns in a first direction and not in a second direction; and
a plurality of second dummy patterns between the plurality of first dummy patterns and overlapping the plurality of pad patterns in the second direction and not in the first direction, wherein the plurality of second dummy patterns are spaced apart from the plurality of first dummy patterns.

2. The semiconductor package of claim 1, wherein the at least one of the plurality of semiconductor chips further comprises:
a plurality of front pads connected to front surfaces of the plurality of pad patterns;
the front insulating layer around the plurality of front pads; and
a support insulating layer between the device layer and the front insulating layer, and around the conductive pattern.

3. The semiconductor package of claim 2, wherein the at least one of the plurality of semiconductor chips further comprises:
a semiconductor substrate;
a through-electrode passing through the semiconductor substrate;
the rear insulating layer disposed on a rear surface of the semiconductor substrate; and
a plurality of rear pads electrically connected to the through-electrode, the rear insulating layer being around the plurality of rear pads, and
wherein the adjacent ones of the plurality of semiconductor chips are electrically connected to each other through direct bonding between the plurality of front pads of first one of the adjacent semiconductor chips and the plurality of rear pads of the second one of the adjacent semiconductor chips.

4. The semiconductor package of claim 3, wherein each of the front insulating layer, the support insulating layer, and the rear insulating layer comprises at least one of SiO₂, SiN, SiCN, or tetraethyloxysilane (TEOS).

5. The semiconductor package of claim 4,
wherein each of the plurality of front pads comprises copper or a copper alloy, and
wherein the conductive pattern comprises at least one of copper, a copper alloy, aluminum, or an aluminum alloy.

6. The semiconductor package of claim 5, wherein central portions of the front surfaces of the plurality of pad patterns directly contact the plurality of front pads, and
wherein edge portions of the front surfaces of the plurality of pad patterns directly contact the front insulating layer.

7. The semiconductor package of claim 2, wherein the conductive pattern comprises a first conductive material having a first thermal expansion coefficient, and each of the plurality of front pads comprises a conductive material having a second thermal expansion coefficient that is lower than the first thermal expansion coefficient.

8. The semiconductor package of claim 1, wherein the interconnection structure comprises at least one interconnection layer and an interconnection via, and
wherein a thickness of the conductive pattern is greater than a thickness of each of the at least one interconnection layer.

9. The semiconductor package of claim 1, wherein a total area of the dummy pattern is larger than a total area of the plurality of pad patterns.

10. The semiconductor package of claim 1, wherein a center of a front surface of each of the plurality of first dummy patterns directly contacts the front insulating layer or the rear insulating layer, and
wherein a center of a front surface of each of the plurality of second dummy patterns directly contacts the front insulating layer or the rear insulating layer.

11. The semiconductor package of claim 1, wherein each of the plurality of first dummy patterns extends in the second direction, and
wherein a portion of each of the plurality of first dummy patterns overlaps the plurality of second dummy patterns in the first direction.

12. A semiconductor package comprising:
a plurality of semiconductor chips, each of the plurality of semiconductor chips comprising at least one of a front insulating layer and a rear insulating layer, adjacent semiconductor chips of the plurality of semiconductor chips being bonded to each other through direct bonding between the front insulating layer of a first one of the adjacent semiconductor chips and the rear insulating layer of a second one of the adjacent semiconductor chips,
wherein at least one of the plurality of semiconductor chips comprises:
a plurality of front pads;
the front insulating layer around each of the plurality of front pads;
a device layer on a rear surface of the front insulating layer, the device layer comprising an interconnection structure electrically connected to the plurality of front pads;
a support insulating layer between the device layer and the front insulating layer; and
a conductive pattern between the interconnection structure and the plurality of front pads and around the conductive pattern,
wherein the conductive pattern comprises:
a plurality of pad patterns electrically connected between the interconnection structure and the plurality of front pads; and
a dummy pattern spaced apart from the plurality of front pads and the plurality of pad patterns,
wherein the dummy pattern comprises a plurality of first dummy patterns extending in a second direction between the plurality of pad patterns, and the plurality of first dummy patterns overlap the plurality of pad patterns in a first direction, and
wherein the plurality of first dummy patterns are spaced apart from each other in the first direction between two adjacent pad patterns, among the plurality of pad patterns.

13. The semiconductor package of claim 12, wherein the plurality of front pads is connected to front surfaces of the plurality of pad patterns,
wherein the at least one of the plurality of semiconductor chips further comprises:
a semiconductor substrate;
a through-electrode passing through the semiconductor substrate;
the rear insulating layer on a rear surface of the semiconductor substrate; and
a plurality of rear pads electrically connected to the through-electrode, the rear insulating layer being around the plurality of rear pads, and
wherein the adjacent semiconductor chips are electrically connected to each other through direct bonding between the plurality of front pads and the plurality of rear pads.

14. The semiconductor package of claim 12, wherein a center of a front surface of each of the plurality of first dummy patterns directly contacts the front insulating layer or the rear insulating layer,
wherein the plurality of pad patterns are configured to transmit a signal to the interconnection structure or receive a signal from the interconnection structure, and
wherein the plurality of first dummy patterns are configured to have a ground or DC voltage.

15. The semiconductor package of claim 12, wherein the interconnection structure comprises at least one interconnection layer and an interconnection via,
wherein a thickness of the conductive pattern is greater than a thickness of the at least one interconnection layer, and
wherein a total area of the dummy pattern is larger than a total area of the plurality of pad patterns.

16. A semiconductor package comprising:
a semiconductor chip comprising:
a front insulating layer;
a plurality of front pads surrounded by the front insulating layer;
a device layer on a rear surface of the front insulating layer and comprising an interconnection structure electrically connected to the plurality of front pads;
a conductive pattern between the interconnection structure and the plurality of front pads;
a support insulating layer between the device layer and the front insulating layer and around the conductive pattern;
a semiconductor substrate on a rear surface of the device layer;
a through-electrode passing through the semiconductor substrate; and
a rear insulating layer on a rear surface of the semiconductor substrate,
wherein the conductive pattern comprises:
a plurality of pad patterns electrically connected between the interconnection structure and the plurality of front pads; and
a dummy pattern spaced apart from the plurality of front pads and the plurality of pad patterns, and
wherein the dummy pattern comprises a plurality of dummy patterns arranged around the plurality of pad patterns, and each of the plurality of dummy patterns extending in an extension direction that is not bent.

17. The semiconductor package of claim 16, wherein first dummy patterns, among the plurality of dummy patterns, overlap the plurality of pad patterns in a first direction,
wherein second dummy patterns, among the plurality of dummy patterns, overlap the plurality of pad patterns in a second direction that is different from the first direction, and
wherein the second dummy patterns are spaced apart from the first dummy patterns.

18. The semiconductor package of claim 17, wherein each of the first dummy patterns extends in the second direction,
wherein a portion of each of the first dummy patterns overlaps the second dummy patterns in the first direction,
wherein each of the second dummy patterns has a shape that is the same as a shape of each of the plurality of pad patterns, and
wherein the second dummy patterns and the plurality of pad patterns are alternately arranged in the second direction.

19. The semiconductor package of claim 16, wherein the interconnection structure comprises at least one interconnection layer and an interconnection via,
wherein a thickness of the conductive pattern is greater than a thickness of each of the at least one interconnection layer, and
wherein a total area of the dummy pattern is larger than a total area of the plurality of pad patterns.

20. The semiconductor package of claim 16, wherein each of the front insulating layer, the support insulating layer, and the rear insulating layer comprises at least one of SiO₂, SiN, SiCN, or tetraethyloxysilane (TEOS),
wherein the plurality of front pads comprise copper or a copper alloy, and
wherein the conductive pattern comprises at least one of copper, a copper alloy, aluminum, or an aluminum alloy.
